(19) United States
(12) Patent Application Publication
(10) Pub. No.: US 2008/0315383 A1
(43) Pub. Date: Dec. 25, 2008

(54) CHIP FRAME FOR OPTICAL DIGITAL PROCESSOR

(75) Inventor: Zzu-Chi Chiu, Taipei (TW)

Correspondence Address: PAI PATENT & TRADEMARK LAW FIRM, 1001 FOURTH AVENUE, SUITE 3200, SEATTLE, WA, 98154, US

(73) Assignee: TONG HSING ELECTRIC INDUSTRIES LTD., Taipei (TW)

(21) Appl. No.: 11/768,191

(22) Filed: Jun. 25, 2007

(51) Int. Cl. H01L 23/02

(52) U.S. Cl. 257/679; 257/E23.18

(57) ABSTRACT

A chip frame for an optical digital processor has a body with a concave seat integrally protruding downward from a bottom surface of the body. Multiple dents are defined on the bottom surface of the body to receive conductive elements such as springs. With the conductive elements, the chip frame can electronically contact ground pads on a circuit board, without needing of conductive epoxy coating.

### BACKGROUND OF THE INVENTION

1. Field of the Invention

The invention relates to a package element for semiconductor devices, and in particular to a chip frame this is used in the package of an optical digital processor.

2. Description of Related Art

With reference to FIG. 3, the package structure of a conventional optical digital processor comprises a chip frame (50) being mounted on a circuit board (40). The optical digital processor is often used as a video processor for optical devices such as the video projector and the rear-projection television.

The circuit board (40) has a top surface, a bottom surface and a rectangular opening (41) defined through the circuit board (40). Multiple signal contacts (42) are formed on the top surface of the circuit board (40) along two opposite edges of the opening (41). Two ground pads (43) also formed on the top surface of the circuit board (40) but along the other two opposite edges respectively of the opening (41).

The chip frame (50) comprises a body (51) and a concave seat (52) formed at the center of the body (51). The chip frame (50) has a bottom surface and a top surface, and the concave seat (52) is lower then the bottom surface of the body (51) as shown from the lateral view. Two slots (53) are defined through the concave seat (52) respectively along two opposite edges of the concave seat (52).

With reference to FIGS. 4 and 5, after the chip frame (50) is mounted on the circuit board (40), the concave seat (52) is positioned in the opening (41) while the signal contacts (42) of the circuit board (40) are exposed from the two slots (53). An optical digital processor chip (60) is mounted on the top surface of the concave seat (52) and electronically connected to the signal contacts (42) by multiple wires through wire-bonding processes. The bottom surface of the chip frame (50) further electronically contacts the ground pads (43) via a coating of conductive epoxy such as silver epoxy (62).

The use of the conductive epoxy (62) to connect the chip frame (50) and the circuit board (40) has some drawbacks. A heat process is necessary to solidify the coating of the conductive epoxy (62) after the conductive epoxy (62) is spread between the chip frame (50) and the circuit board (40). However, the heating process may cause obvious chaps on the conductive epoxy (62). The chaps of the conductive epoxy (62) increase the junction impedance between the chip frame (50) and the circuit board (40) and sometimes in worse situations will result in a broken circuit. In addition to the foregoing, the cost of the conductive epoxy is very expensive.

### SUMMARY OF THE INVENTION

The objective of the present invention is to provide a chip frame that electronically contact to ground pads of a circuit board without using any coating of the conductive epoxy.

To achieve the objective, the chip frame comprising:

a body having a bottom surface;

a concave seat protruding downward from the bottom surface of the chip frame and having two through slots respectively along two opposite edges of the concave seat;

multiple dents formed on the bottom surface of the chip frame; and

multiple conductive elements respectively held in the multiple dents to contact the ground pads of the circuit board when the chip frame is mounted on the circuit board.

Other objectives, advantages and novel features of the invention will become more apparent from the following detailed description when taken in conjunction with the accompanying drawings.

### BRIEF DESCRIPTION OF THE DRAWINGS

FIG. 1 is an exploded perspective view showing a chip frame of the present invention being separated from a circuit board;

FIG. 2 is a cross-sectional view of the chip frame of the present invention being mounted on the circuit board;

FIG. 3 is an exploded perspective view showing a conventional chip frame being separated from a circuit board;

FIG. 4 is a cross-sectional view of the conventional chip frame being mounted on the circuit board; and

FIG. 5 is a perspective view of the conventional chip frame being mounted on the circuit board.

### DETAILED DESCRIPTION OF THE PREFERRED EMBODIMENT

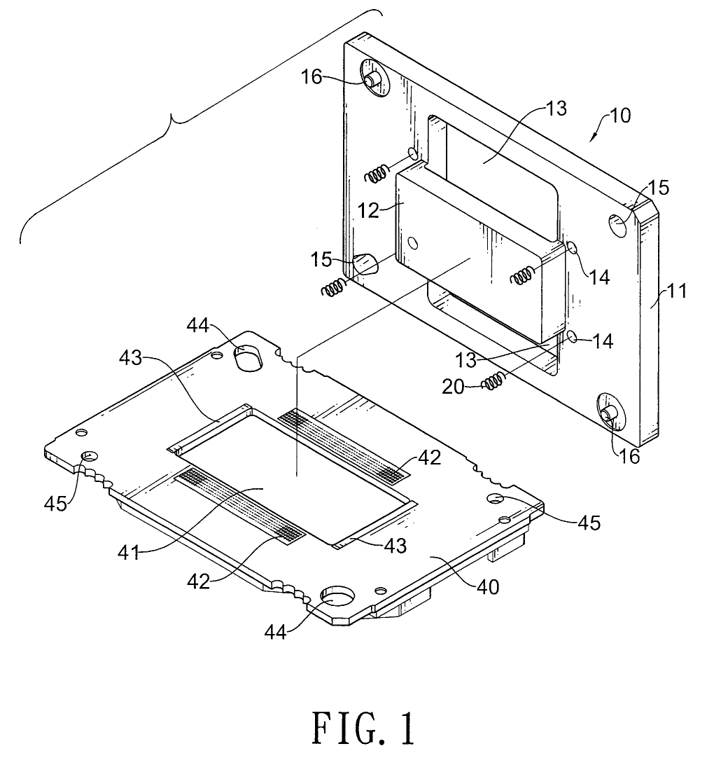

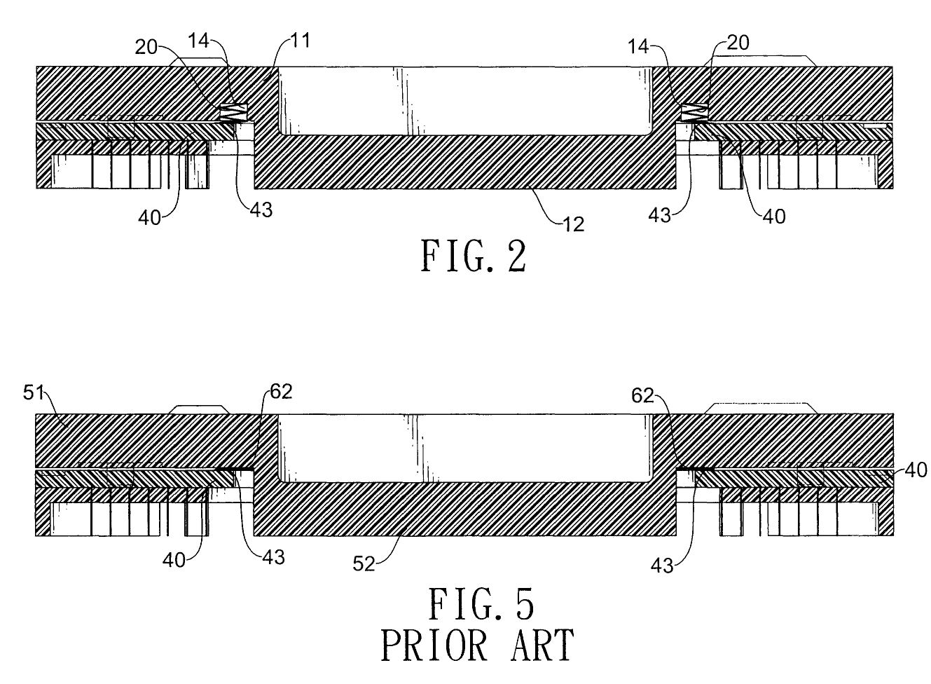

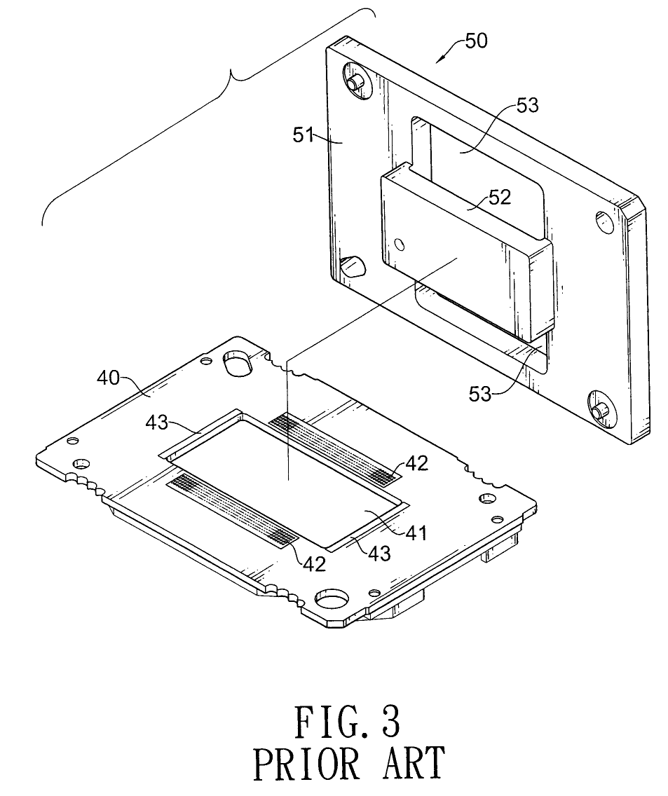

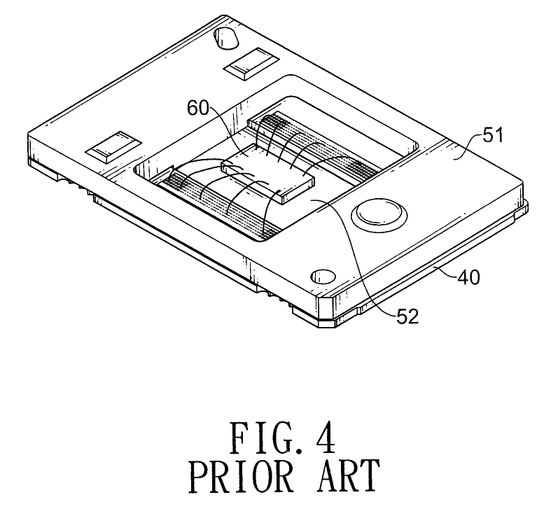

A preferred embodiment of the invention is illustrated in FIGS. 1 and 2. A chip frame (10) in accordance with the present invention is to be mounted on a circuit board (40). The circuit board (40) has a top surface, a bottom surface and a rectangular opening (41) defined through the circuit board (40). Multiple signal contacts (42) are formed on the top surface of the circuit board (40) along two opposite edges of the opening (41). Two ground pads (43) also formed on the top surface of the circuit board (40) but along the other two opposite edges respectively of the opening (41). The circuit board (40) at its four corners further define with engaging holes (44) and orientating holes (45).

The shape of chip frame (10) is corresponding to the circuit board (40), both are formed as a rectangular shape in this embodiment. The chip frame (10) comprises a body (11) and a concave seat (12) integrally formed at a central portion of the body (11). The chip frame (10) has a bottom surface and a top surface, and the concave seat (12) protrudes from the bottom surface of the chip frame (10). Therefore, the concave seat (12) is lower then the bottom surface of the body (11). Two slots (13) are defined through the concave seat (12) respectively along two opposite edges of the concave seat (12). Multiple dents (14) are defined on the bottom surface of the body (10) and not through the body (10). The positions of the dents (14) are corresponding to the ground pads (43) of the circuit board (40). In this embodiment, four dents (14) are formed on the bottom surface of the chip frame (10) and respectively near the four corners of the concave seat (12). The chip frame (10) also has orientating holes (15) corresponding to that of the circuit board (40) and further at the bottom surface forms multiple protrusions (16) for respectively inserting to the engaging holes (45).

When assembling the chip frame (10) to the circuit board (40), multiple conductive elements (20) are respectively held in the dents (14) to achieve an electronic contact between the chip frame (10) and the ground pads (43). The embodiment uses multiple springs as the conductive elements (20). Each spring has two ends that are respectively abut against the chip frame (10) and the circuit board (40). In addition to the springs, the conductive elements (20) can be fabricated in other types such as stubs.

After the chip frame (10) is mounted on the circuit board (40), the concave seat (12) is positioned in the opening (41) while the signal contacts (42) of the circuit board (40) are exposed from the two slots (13). An optical digital processor chip is mounted on the top surface of the concave seat (12) and electronically connected to the signal contacts (42) by multiple wires through wire-bonding processes. When the wire-boding processes are completed, subsequent packaging processes are used to encapsulate the chip frame (10), the circuit board (40) and the optical digital processor to form an optical digital processor.

In the present invention, the conductive elements such as springs are used to achieve an electronic concoction between the ground pads and the chip frame. Therefore, the problems resulting from the use of the conductive expose are avoided.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A chip frame for an optical digital processor that comprises a circuit board, the circuit board having a top surface, an opening defined through the circuit board, and ground pads formed on the top surface and along two opposite edges of the opening, the chip frame comprising:
a body having a bottom surface;
a concave seat protruding downward from the bottom surface of the chip frame and having two through slots respectively along two opposite edges of the concave seat;
multiple dents formed on the bottom surface of the body; and
multiple conductive elements respectively held in the multiple dents to contact the ground pads of the circuit board when the chip frame is mounted on the circuit board.

2. The chip frame as claimed in claim 1, wherein the multiple conductive elements are springs.

3. The chip frame as claimed in claim 1, wherein the multiple dents are formed at positions that correspond to the ground pads of the circuit board.
